(19) United States
(12) Patent Application Publication
(10) Pub. No.: US 2011/0001205 A1
(43) Pub. Date: Jan. 6, 2011

(54) Image sensor and semiconductor device including the same

(75) Inventors: Sang-Chul Sul, Suwon-si (KR); Yoon-Dong Park, Yongin-si (KR); Myung-Bok Lee, Suwon-si (KR); Young-Gu Jin, Hwaseiong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/801,745

(22) Filed: Jun. 23, 2010

(30) Foreign Application Priority Data
Jul. 6, 2009 (KR) 10-2009-0061092

(51) Int. Cl. H01L 31/0232; H04N 5/225

(52) U.S. Cl. 257/432; 348/340; 257/E31.127

(57) ABSTRACT

Example embodiments relate to a three-dimensional image sensor including a color pixel array on a substrate, a distance pixel array on the substrate, an RGB filter on the color pixel array and configured to allow visible light having a first wavelength to pass, a near infrared light filter on the distance pixel array and configured to allow near infrared light having a second wavelength to pass, and a stack type single band filter on the RGB filter and the near infrared light filter and configured to allow light having a third wavelength between the first wavelength and the second wavelength to pass. According to example embodiments, a semiconductor device may include a color pixel array on a substrate; a distance pixel array on the substrate; a light-inducing member on the color pixel array and the distance pixel array; a RGB filter on the light-inducing member and configured to allow visible light to pass; a near infrared light filter on the light-inducing member and configured to allow near infrared light to pass; and a plurality of lenses on the RGB filter and the near infrared light filter.

### CROSS-REFERENCE TO RELATED APPLICATIONS

This application claims priority under 35 USC §119 to Korean Patent Application No. 10-2009-0061092, filed on Jul. 6, 2009 in the Korean Intellectual Property Office (KIPO), the contents of which are herein incorporated by reference in their entirety.

### BACKGROUND

1. Field

Example embodiments relate to a three-dimensional image sensor and a semiconductor device including the same. Particularly, example embodiments relate to a three-dimensional image sensor that provides image information and distance information, and a semiconductor device including the image sensor.

2. Description

A conventional CMOS image sensor may provide only an image. The conventional CMOS image sensor is shown in FIG. 1.

Referring to FIG. 1, the CMOS image sensor may include an active color filter pixel array region 20 and a CMOS control circuit 30. The active color filter pixel array region 20 may include a plurality of unit pixels 22 arranged in a matrix.

The CMOS control circuit 30 may be arranged around/besides the active color pixel array region 20. The CMOS control circuit 30 may include a plurality of CMOS transistors. The CMOS control circuit 30 may provide the unit pixels 22 of the active color pixel array region 20 with signals. Further, the CMOS control circuit 30 may control the signals.

The unit pixel 22 may include a photo diode, a transfer transistor, a reset transistor, a drive transistor, and/or a selection transistor. The photo diode may receive light to generate photocharges. The transfer transistor may transfer the photocharges to a floating diffusion region. The reset transistor may periodically reset the photocharges in the floating diffusion region. The drive transistor may function as a source follower buffer amplifier. The drive transistor may buffer signals in accordance with the photocharges in the floating diffusion region. The selection transistor may function as a switch for selecting the pixels 22.

FIG. 2A is an example cross-sectional view illustrating the photodiode of the unit pixel 22, and FIG. 2B is a graph showing a light spectrum of the unit pixel 22.

Referring to FIG. 2A, a photodiode layer 40 may be formed on a semiconductor substrate. A color filter 45 and a lens 50 may be sequentially formed on the photodiode layer 40.

A filter 60 may be arranged over the lens 50. The filter 60 may allow visible light to pass. In contrast, the filter 60 may block ultraviolet light.

The conventional color image sensor may provide only the image information. However, the conventional color image sensor may not provide distance information.

### SUMMARY

According to example embodiments, a three-dimensional image sensor may include a color pixel array on a substrate, a distance pixel array on the substrate, an RGB filter on the color pixel array and configured to allow a visible light having a first wavelength to pass, a near infrared ray filter on the distance pixel array and configured to allow a near infrared ray having a second wavelength to pass through, and a stack type single band filter on the RGB filter and the near infrared ray filter and configured to allow a light having a third wavelength between the first wavelength and the second wavelength to pass.

According to example embodiments, the first wavelength may be about 400 nm to about 700 nm, the second wavelength may be no less than about 830 nm and the third wavelength may be about 400 nm to about 900 nm.

According to example embodiments, the RGB filter may block infrared light.

According to example embodiments, the near infrared light filter may block visible light.

According to example embodiments, the RGB filter and the infrared filter include a polymer or a dye that selectively blocks a light of a desired wavelength.

According to example embodiments, the stack type filter includes layers of silicon oxide and titanium oxide of varying thicknesses.

According to example embodiments, the stack type filter is a single band filter.

According to example embodiments, the stack type filter is a dual band filter.

According to example embodiments, the near infrared filter has a multi-layered structure or a single layered structure including pigment mixtures or pigment and dye mixtures.

According to example embodiments, the near infrared light filter has a multi-layered structure including at least two inorganic materials that have different reflectivities.

According to example embodiments, an optical system may include an image sensor and a camera lens module on the image sensor.

According to example embodiments, a system may include the optical system, the optical system being configured to provide image information and distance information.

According to example embodiments, a semiconductor device may include a color pixel array on a substrate, a distance pixel array on the substrate, a light-inducing member on the color pixel array and the distance pixel array, a RGB filter on the light-inducing member to allow visible light to pass through, a near infrared light filter on the light-inducing member and configured to allow a near infrared light to pass, and a plurality of lenses on the RGB filter and the near infrared light filter.

According to example embodiments, the RGB filter and the near infrared light filter may include pigment or dye.

According to example embodiments, the near infrared light filter may have a multi-layered structure including at least two inorganic materials that have different reflectivities.

According to example embodiments, the lenses may include microlenses.

According to example embodiments, the light-inducing member may include a resin layer.

According to example embodiments, an optical system may include the semiconductor device, a stack type filter on the semiconductor device and a camera lens module on the stack type filter.

### BRIEF DESCRIPTION OF THE DRAWINGS

The above and other features and advantages will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a circuit diagram illustrating a conventional CMOS image sensor;

FIG. 2A is a cross-sectional view illustrating a photodiode of a unit pixel in FIG. 1

FIG. 2B is a graph showing a light spectrum of the unit pixel in FIG. 1.

FIG. 3 is a perspective view illustrating a three-dimensional optical system, according to example embodiments;

FIG. 4 is a cross-sectional view illustrating an RGB-Z chip and a stack type single band filter of the optical system in FIG. 3, according to example embodiments;

FIG. 5 is a graph showing transmittance of the filters in FIG. 4, according to example embodiments;

FIG. 6 is a graph showing transmittance of a filter, according to example embodiments;

FIG. 7 is a cross-sectional view illustrating the filter in FIG. 6, according to example embodiments;

FIG. 8 is a graph showing transmittance of a filter, according to example embodiments;

FIG. 9 is a cross-sectional view illustrating the filter in FIG. 8, according to example embodiments;

FIG. 10 is a graph showing transmittance of a filter, according to example embodiments;

FIG. 11 is a cross-sectional view illustrating the filter in FIG. 10, according to example embodiments;

FIG. 12 is a cross-sectional view illustrating an RGB-Z chip, according to example embodiments;

FIG. 13 is a graph showing transmittance of the filter in FIG. 12, according to example embodiments;

FIG. 14 is a graph showing transmittance of the filter in FIG. 12, according to example embodiments;

FIG. 15 is a cross-sectional view illustrating a filter, according to example embodiments;

FIG. 16 is a plan view illustrating an RGB chip according to example embodiments;

FIG. 17 is a cross-sectional view illustrating the RGB chip in FIG. 16;

FIG. 18 is a front view illustrating a cellular phone including the optical system illustrated in FIG. 3, according to example embodiments; and

FIG. 19 is a block diagram illustrating a system including the optical system illustrated in FIG. 3, according to example embodiments.

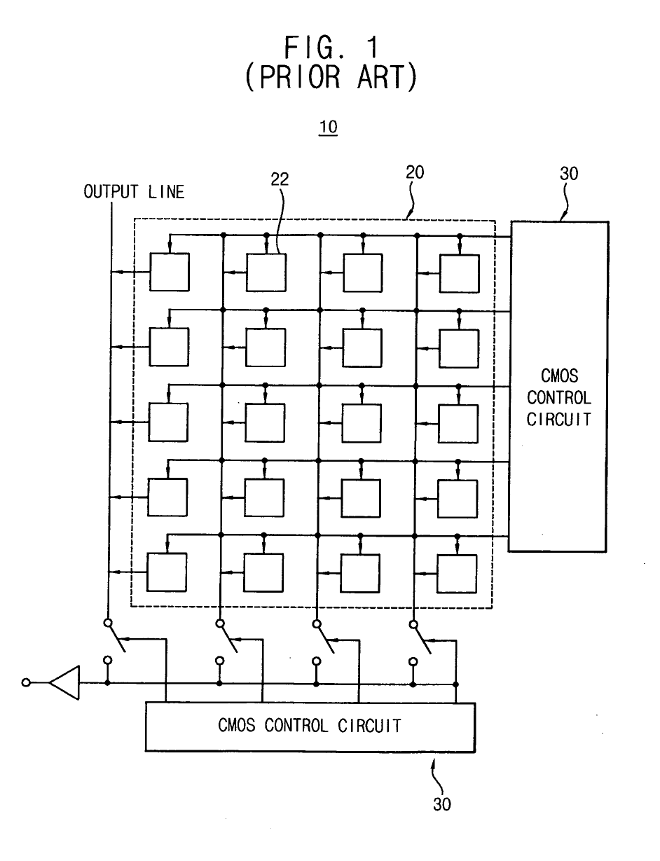

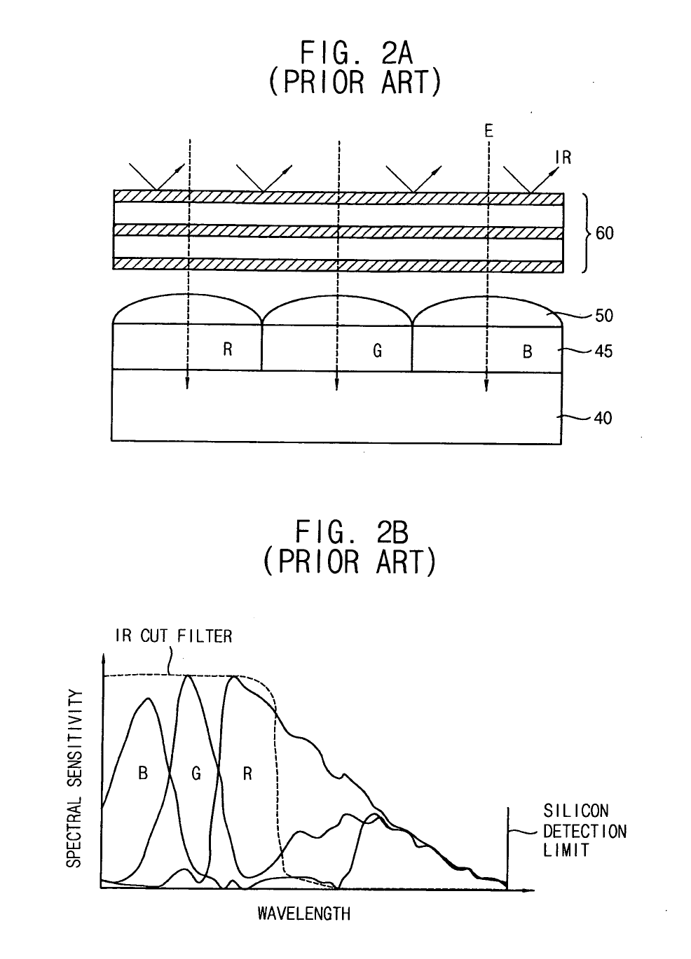

### DETAILED DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Hereinafter, example embodiments will be explained in detail with reference to the accompanying drawings.

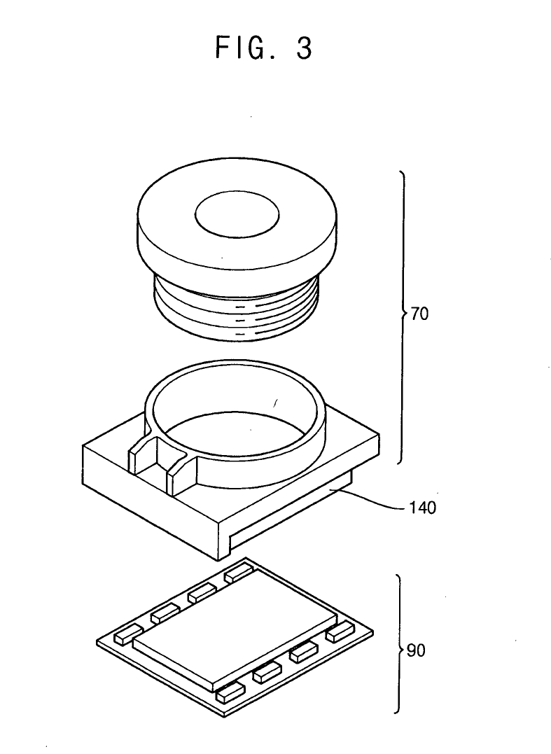

FIG. 3 is a perspective view illustrating a three-dimensional optical system according to example embodiments.

Referring to FIG. 3, an optical system may include a camera lens module 70, a stack type single band filter 140 and an RGB-Z chip 90. The stack type single band filter 140 may be attached to a lower surface of the camera lens module 70. The stack type single band filter 140 may allow visible light and infrared light to pass through. An image sensor, according to example embodiments, may include the stack type single band filter 140 and/or the RGB-Z chip 90. However, the stack type single band filter 140 may not be the only filter used in the optical system and the stack type single band filter 140 may be substituted with various other types of filters, for example, a stack type dual band filter (described below). The RGB-Z chip 90 may include a color pixel array and a distance pixel array. The color pixel array may provide image information. The distance pixel array may provide distance information.

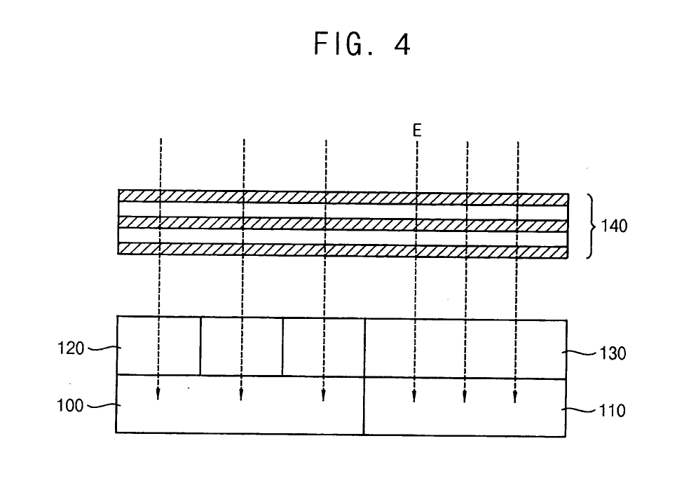

FIG. 4 is a cross-sectional view illustrating the RGB-Z chip and the stack type single band filter of the optical system in FIG. 3, according to example embodiments.

Referring to FIG. 4, the RGB-Z chip may include a semiconductor substrate having a color pixel array photodiode region 100 and a distance pixel array region 110. An RGB filter 120 may be formed on the color pixel array photodiode region 100. The RGB filter 120 may allow visible light having a first wavelength to pass through. In contrast, the RGB filter 120 may block a near infrared light having a second wavelength. In example embodiments, the RGB filter 120 may include a polymer. A near infrared light filter 130 may be formed on the distance pixel array region 110. The near infrared ray filter 130 may block the visible light having the first wavelength. In contrast, the near infrared light filter 130 may allow the infrared light having the second wavelength to pass through. In example embodiments, the near infrared ray filter 130 may include a polymer.

In example embodiments, the RGB filter 120 and the near infrared light filter 130 may include materials such as a dye capable of selectively blocking a light having a desired wavelength.

The stack type single band filter 140 may be arranged over the RGB filter 120 and the near infrared light filter 130. The stack type single band filter 140 may allow light having a third wavelength between the first wavelength and the second wavelength to pass through. In example embodiments, the stack type single band filter 140 may include silicon oxide and/or titanium oxide.

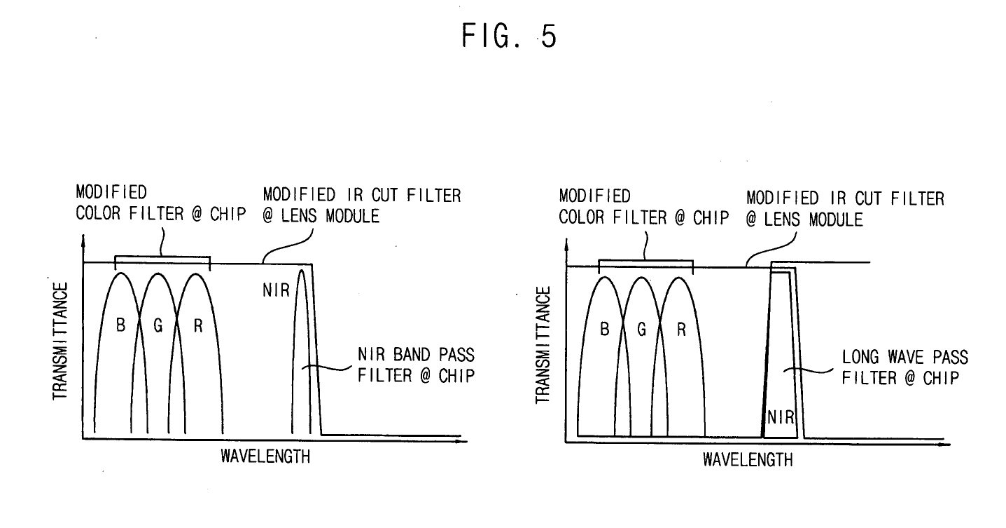

FIG. 5 is a graph showing transmittance of the filters in FIG. 4.

Referring to FIG. 5, the near infrared light filter 130 may be a first type filter shown in left region of FIG. 5 or a second type filter shown in right region of FIG. 5. The first type filter may allow the infrared light having the second wavelength to pass. The second type filter may allow infrared light having a wavelength no less than (greater than) a critical/desired wavelength to pass.

Light may be incident on the camera lens module 70. The stack type single band filter 140 may allow light having the third wavelength to pass through. The light having the third wavelength may be incident on the RGB filter 120. The RGB filter 120 may allow the visible light having the first wavelength to pass through. In contrast, the RGB filter 120 may block the infrared light. Thus, only the visible light may be incident on the color pixel array photodiode region 100.

Further, the light having the third wavelength may be incident on the near infrared light filter 130. The near infrared light filter 130 may allow the infrared light having the second wavelength to pass through. In contrast, the near infrared light 130 may block the visible light. Thus, only the infrared light may be incident to the distance pixel region 110.

According to example embodiments, the optical system may include the RGB-Z chip having the color pixel array and the distance pixel array. Thus, the optical system may provide the image information and the distance information.

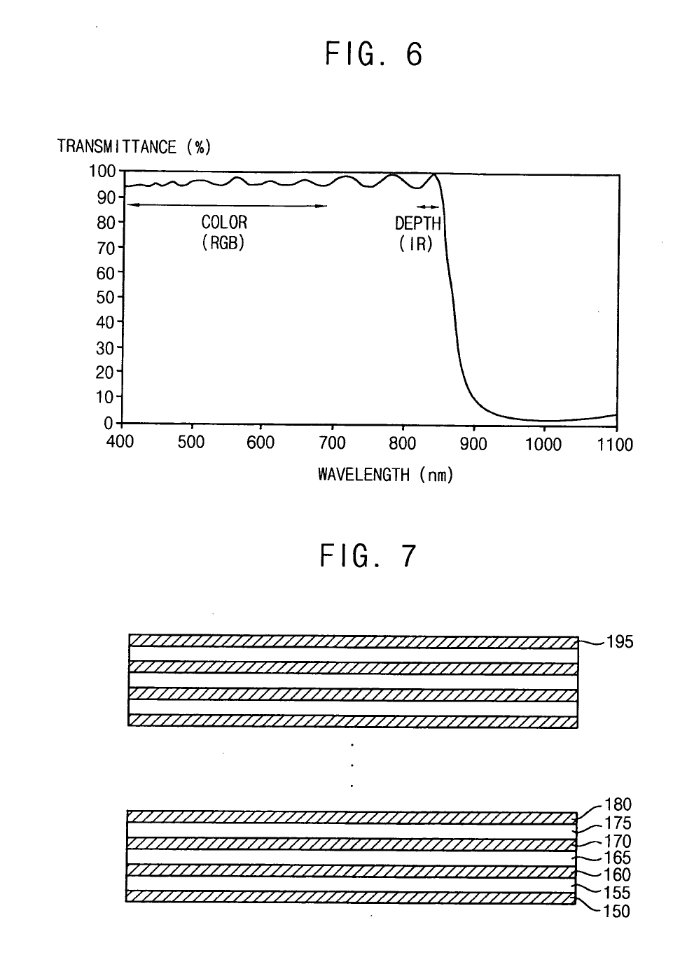

FIG. 6 is a graph showing transmittance of a stack type single band filter according to example embodiments.

Referring to FIG. 6, the stack type single band filter may allow visible light having a wavelength of about 400 nm to about 700 nm and no less than about 95% of a near infrared light (wavelength of about 830 nm to about 870 nm) to pass through. In contrast, the stack type single band filter may block light having a wavelength of no less than about 900 nm.

FIG. 7 is a cross-sectional view illustrating the stack type single band filter in FIG. 6.

TABLE 1

| Layer | Material | Thickness (nm) |
|---|---|---|
| 1 | SiO2 | 70 |
| 2 | TiO2 | 20 |
| 3 | SiO2 | 5 |
| 4 | TiO2 | 70 |
| 5 | SiO2 | 25 |
| 6 | TiO2 | 15 |
| 7 | SiO2 | 130 |
| 8 | TiO2 | 10 |
| 9 | SiO2 | 30 |
| 10 | TiO2 | 65 |
| 11 | SiO2 | 10 |
| 12 | TiO2 | 25 |
| 13 | SiO2 | 150 |
| 14 | TiO2 | 15 |
| 15 | SiO2 | 15 |
| 16 | TiO2 | 75 |
| 17 | SiO2 | 20 |
| 18 | TiO2 | 20 |
| 19 | SiO2 | 165 |
| 20 | TiO2 | 90 |
| 21 | SiO2 | 15 |
| 22 | TiO2 | 15 |
| 23 | SiO2 | 160 |
| 24 | TiO2 | 20 |
| 25 | SiO2 | 5 |
| 26 | TiO2 | 75 |
| 27 | SiO2 | 25 |
| 28 | TiO2 | 10 |
| 29 | SiO2 | 150 |
| 30 | TiO2 | 20 |
| 31 | SiO2 | 20 |

Referring to FIG. 7, a first layer 150 may include a silicon oxide layer having a thickness of about 70 nm. A second layer 155 may include a titanium oxide layer having a thickness of about 20 nm. A third layer 160 may include a silicon oxide layer having a thickness of about 5 nm. A fourth layer 165 may include a titanium oxide layer having a thickness of about 70 nm. A fifth layer 170 may include a silicon oxide layer having a thickness of about 25 nm. A sixth layer 175 may include a titanium oxide layer having a thickness of about 15 nm. A seventh layer 180 may include a silicon oxide layer having a thickness of about 130 nm. A thirty-first layer 195 may include a silicon oxide layer having a thickness of about 20 nm.

The stack type single band filter including the silicon oxide layer and the titanium oxide layer sequentially stacked may allow light having a wavelength of about 400 nm to about 900 nm to pass through. In contrast, the stack type single band filter may block the light having a wavelength greater than about 900 nm.

The transmittance of light through the stack type single band filter may be determined in accordance with reflectivities, extinction coefficients, thickness differences, or the like.

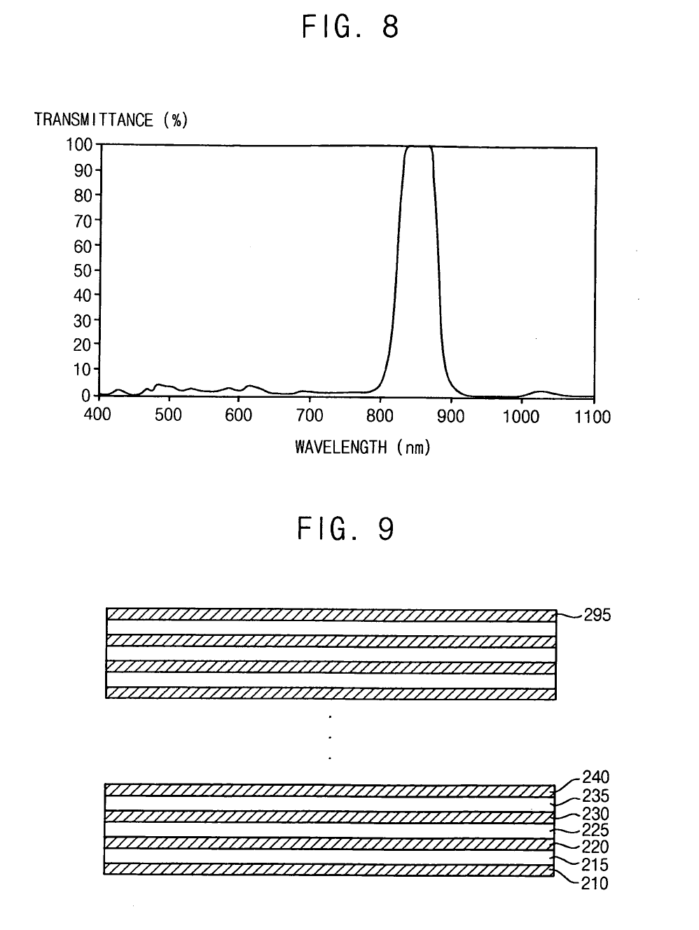

FIG. 8 is a graph showing transmittance of a stack type single band filter according to example embodiments.

Referring to FIG. 8, the stack type single band filter may block light having a wavelength less than about 800 nm and light having a wavelength greater than about 900 nm. The stack type single band filter may allow light having a wavelength of about 800 nm to about 900 nm to pass through.

FIG. 9 is a cross-sectional view illustrating the stack type single band filter in FIG. 8.

TABLE 2

| Layer | Material | Thickness (nm) |
|---|---|---|
| 1 | SiO2 | 85 |
| 2 | TiO2 | 25 |
| 3 | SiO2 | 5 |
| 4 | TiO2 | 75 |
| 5 | SiO2 | 20 |
| 6 | TiO2 | 10 |
| 7 | SiO2 | 160 |
| 8 | TiO2 | 15 |
| 9 | SiO2 | 5 |
| 10 | TiO2 | 70 |
| 11 | SiO2 | 10 |
| 12 | TiO2 | 20 |
| 13 | SiO2 | 180 |
| 14 | TiO2 | 15 |
| 15 | SiO2 | 10 |
| 16 | TiO2 | 100 |
| 17 | SiO2 | 180 |
| 18 | TiO2 | 110 |
| 19 | SiO2 | 180 |
| 20 | TiO2 | 110 |
| 21 | SiO2 | 180 |
| 22 | TiO2 | 110 |
| 23 | SiO2 | 170 |
| 24 | TiO2 | 20 |
| 25 | SiO2 | 10 |
| 26 | TiO2 | 80 |
| 27 | SiO2 | 10 |
| 28 | TiO2 | 20 |
| 29 | SiO2 | 180 |
| 30 | TiO2 | 20 |
| 31 | SiO2 | 20 |
| 32 | TiO2 | 60 |
| 33 | SiO2 | 15 |
| 34 | TiO2 | 15 |

Referring to FIG. 9, a first layer 210 may include a silicon oxide layer having a thickness of about 85 nm. A second layer 215 may include a titanium oxide layer having a thickness of about 25 nm. A third layer 220 may include a silicon oxide layer having a thickness of about 5 nm. A fourth layer 225 may include a titanium oxide layer having a thickness of about 75 nm. A fifth layer 230 may include a silicon oxide layer having a thickness of about 20 nm. A sixth layer 235 may include a titanium oxide layer having a thickness of about 10 nm. A seventh layer 240 may include a silicon oxide layer having a thickness of about 160 nm. A thirty-fourth layer 295 may include a titanium oxide layer having a thickness of about 15 nm.

The stack type single band filter including the silicon oxide layer and the titanium oxide layer sequentially stacked may allow the light having a wavelength of about 800 nm to about 900 nm to pass through.

The transmittance of the light through the stack type single band filter may be determined in accordance with reflectivities, extinction coefficients, thickness differences, or the like.

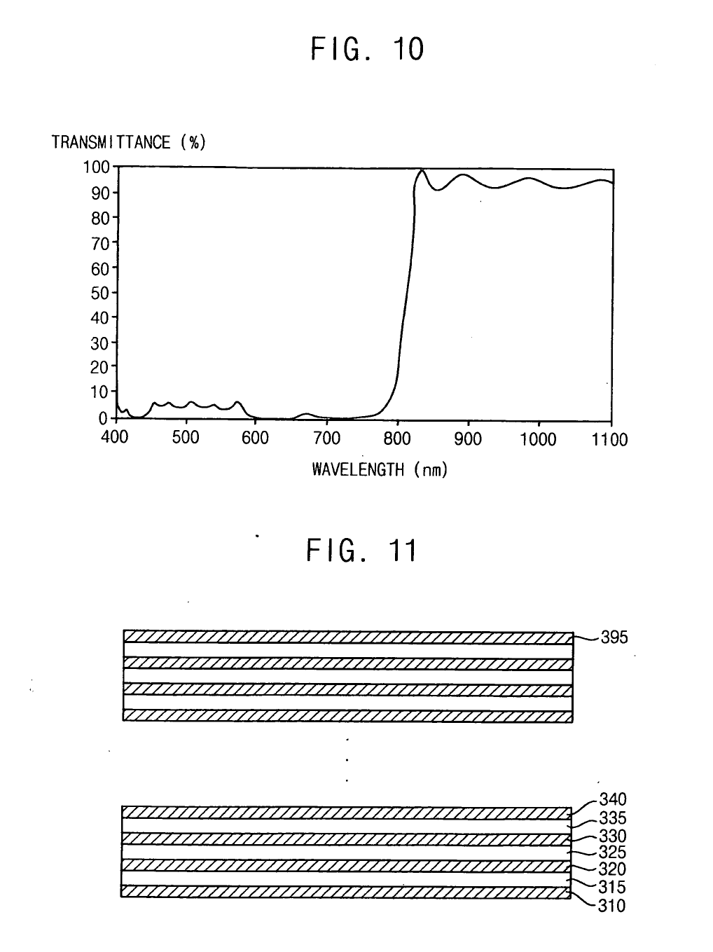

FIG. 10 is a graph showing transmittance of a stack type single band filter according to example embodiments.

Referring to FIG. 10, the stack type single band filter may allow infrared light having a wavelength of no less than about 800 nm to pass through. In contrast, the stack type single band filter may block an infrared light having a wavelength of no greater than about 800 nm.

Thus, infrared light having a desired wavelength may be obtained using the stack type single band filter. For example, the stack type single band filter may be used for a distance detection system using infrared data.

FIG. 11 is a cross-sectional view illustrating the filter in FIG. 10.

TABLE 3

| layer | material | Thickness (nm) |
|---|---|---|
| 1 | TiO2 | 35 |
| 2 | SiO2 | 85 |
| 3 | TiO2 | 50 |
| 4 | SiO2 | 70 |
| 5 | TiO2 | 30 |
| 6 | SiO2 | 75 |
| 7 | TiO2 | 50 |
| 8 | SiO2 | 30 |
| 9 | TiO2 | 55 |
| 10 | SiO2 | 100 |
| 11 | TiO2 | 65 |
| 12 | SiO2 | 100 |
| 13 | TiO2 | 55 |
| 14 | SiO2 | 90 |
| 15 | TiO2 | 80 |
| 16 | SiO2 | 70 |
| 17 | TiO2 | 45 |
| 18 | SiO2 | 105 |

Referring to FIG. 11, a first layer 310 may include a titanium oxide layer having a thickness of about 35 nm. A second layer 315 may include a silicon oxide layer having a thickness of about 85 nm. A third layer 320 may include a titanium oxide layer having a thickness of about 50 nm. A fourth layer 325 may include a silicon oxide layer having a thickness of about 70 nm. A fifth layer 330 may include a titanium oxide layer having a thickness of about 30 nm. A sixth layer 335 may include a silicon oxide layer having a thickness of about 75 nm. A seventh layer 340 may include a titanium oxide layer having a thickness of about 50 nm. An eighteenth layer 395 may include a silicon oxide layer having a thickness of about 105 nm.

The stack type single band filter including the silicon oxide layer and the titanium oxide layer sequentially stacked may allow the infrared light having the wavelength of no less than about 800 nm to pass through.

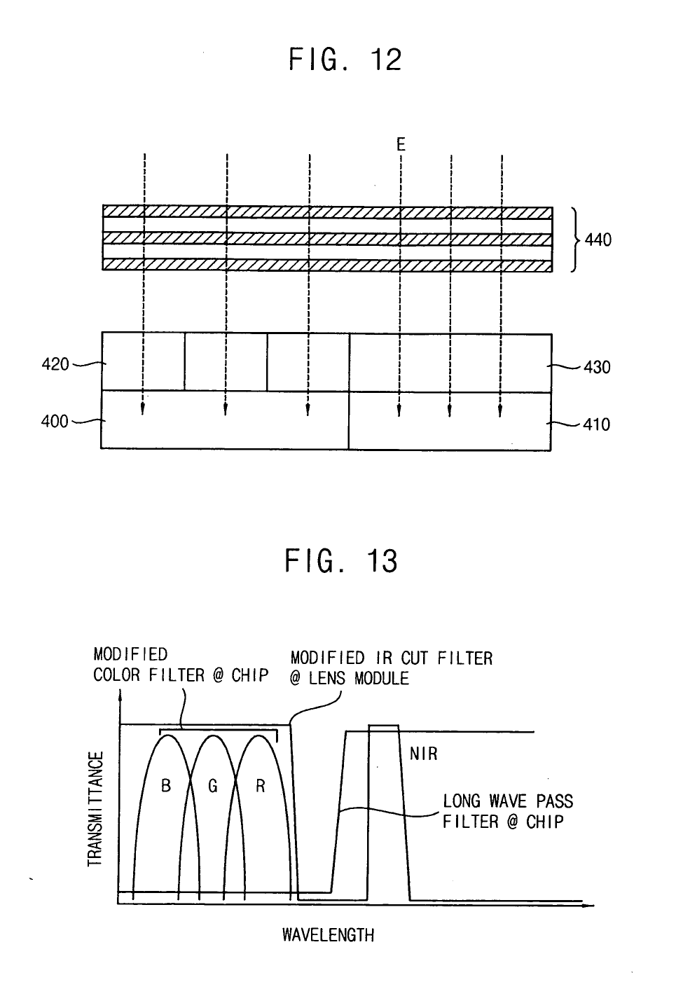

FIG. 12 is a cross-sectional view illustrating an RGB-Z chip and a stack type dual band filter 440 that may be used in the optical system of FIG. 3, according to example embodiments.

Referring to FIG. 12, the RGB-Z chip may include a semiconductor substrate having a color pixel array photodiode region 400 and a distance pixel array region 410. An RGB filter 420 may be formed on the color pixel array photodiode region 400. The RGB filter 420 may allow visible light having a first wavelength to pass through. In contrast, the RGB filter 420 may block a near infrared light having a second wavelength. In example embodiments, the RGB filter 420 may include polymer. A near infrared light filter 430 may be formed on the distance pixel array region 410. The near infrared light filter 430 may block the visible light having the first wavelength. In contrast, the near infrared light filter 430 may allow the infrared light having the second wavelength to pass through. In example embodiments, the near infrared light filter 430 may include polymer.

In example embodiments, the near infrared light filter 430 may have a multi-layered structure including an inorganic material. Alternatively, the near infrared light filter 430 may have a single layer structure including pigment mixtures, pigment and/or dye mixtures.

A stack type dual band filter 440 may be arranged over the RGB filter 420 and/or the near infrared light filter 430. The stack type dual band filter 440 may allow a visible light having a wavelength of about 400 nm to about 700 nm and an infrared light having a wavelength of about 830 nm to about 870 nm to pass through. In example embodiments, the stack type dual band filter 440 may include silicon oxide and/or titanium oxide.

The stack type dual band filter 440 may be formed with relative ease as compared to the stack type single band filter 140. Further, the stack type dual band filter 440 may have a sufficient margin with respect to a limit wavelength of an infrared light filter.

That is, the stack type single band filter 140 may have a limit wavelength of about 830 nm. In contrast, the stack type dual band filter 440 may have a limit wavelength of about 700 nm to about 830 nm.

FIG. 13 is a graph showing transmittance of the filters in FIG. 12, according to example embodiments.

Referring to FIG. 13, a modified IR cut filter may allow visible light having a wavelength of about 400 nm to about 700 nm and infrared light having a wavelength of about 830 nm to about 870 nm to pass through. Further, a long wave pass filter may allow infrared light having a wavelength to pass through.

When the modified IR cut filter and the long wave pass filter may be overlapped with each other, the visible light having the wavelength of about 400 nm to about 700 nm may pass through a first band of the modified IR cut filter. The infrared light having the wavelength of about 830 nm to about 870 nm may be overlapped in the long wave pass filter, so that a limit wavelength may expand.

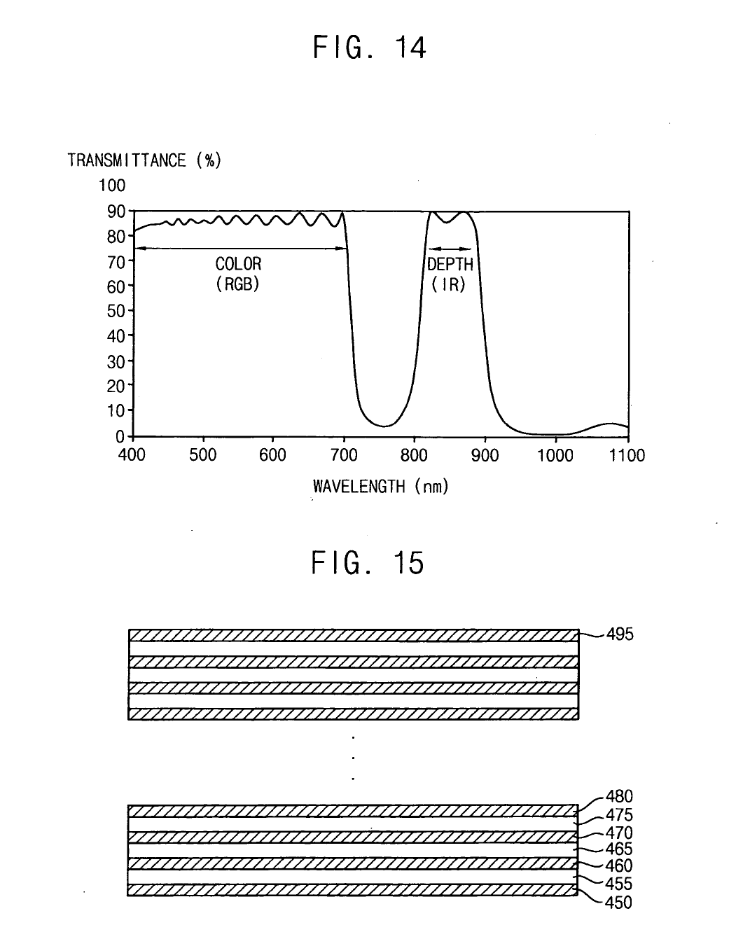

FIG. 14 is a graph showing transmittance of the stack type dual band filter 440 in FIG. 12, according to example embodiments.

Referring to FIG. 14, the stack type dual band filter may allow light having a wavelength of about 400 nm to about 700 nm and about 95% of infrared light having a wavelength of about 800 nm to about 900 nm to pass through. In contrast, the stack type dual band filter may block an infrared light having a wavelength of no less than about 900 nm.

FIG. 15 is a cross-sectional view illustrating the stack type dual filter in FIG. 14.

TABLE 4

| Layer | Material | Thickness (nm) |
|---|---|---|
| 1 | SiO2 | 65 |
| 2 | TiO2 | 80 |
| 3 | SiO2 | 10 |
| 4 | TiO2 | 10 |
| 5 | SiO2 | 155 |
| 6 | TiO2 | 105 |
| 7 | SiO2 | 30 |
| 8 | TiO2 | 15 |
| 9 | SiO2 | 160 |
| 10 | TiO2 | 5 |
| 11 | SiO2 | 30 |
| 12 | TiO2 | 100 |
| 13 | SiO2 | 150 |
| 14 | TiO2 | 100 |
| 15 | SiO2 | 155 |
| 16 | TiO2 | 100 |
| 17 | SiO2 | 30 |
| 18 | TiO2 | 10 |
| 19 | SiO2 | 175 |
| 20 | TiO2 | 10 |
| 21 | SiO2 | 30 |
| 22 | TiO2 | 100 |
| 23 | SiO2 | 160 |
| 24 | TiO2 | 90 |
| 25 | SiO2 | 15 |
| 26 | TiO2 | 10 |
| 27 | SiO2 | 330 |
| 28 | TiO2 | 15 |
| 29 | SiO2 | 20 |
| 30 | TiO2 | 80 |
| 31 | SiO2 | 25 |
| 32 | TiO2 | 15 |
| 33 | SiO2 | 220 |
| 34 | TiO2 | 10 |
| 35 | SiO2 | 30 |
| 36 | TiO2 | 60 |
| 37 | SiO2 | 15 |
| 38 | TiO2 | 30 |
| 39 | SiO2 | 190 |
| 40 | TiO2 | 10 |

Referring to FIG. 15, a first layer 450 may include a silicon oxide layer having a thickness of about 65 nm. A second layer 455 may include a titanium oxide layer having a thickness of about 80 nm. A third layer 460 may include a silicon oxide layer having a thickness of about 10 nm. A fourth layer 465 may include a titanium oxide layer having a thickness of about 10 nm. A fifth layer 470 may include a silicon oxide layer having a thickness of about 155 nm. A sixth layer 475 may include a titanium oxide layer having a thickness of about 105 nm. A seventh layer 480 may include a silicon oxide layer having a thickness of about 30 nm. A fortieth layer 495 may include a titanium oxide layer having a thickness of about 10 nm.

The stack type dual band filter including the silicon oxide layer and the titanium oxide layer sequentially stacked may allow visible light having the wavelength of about 400 nm to about 700 nm and the infrared light having the wavelength of about 800 nm to about 900 nm to pass through.

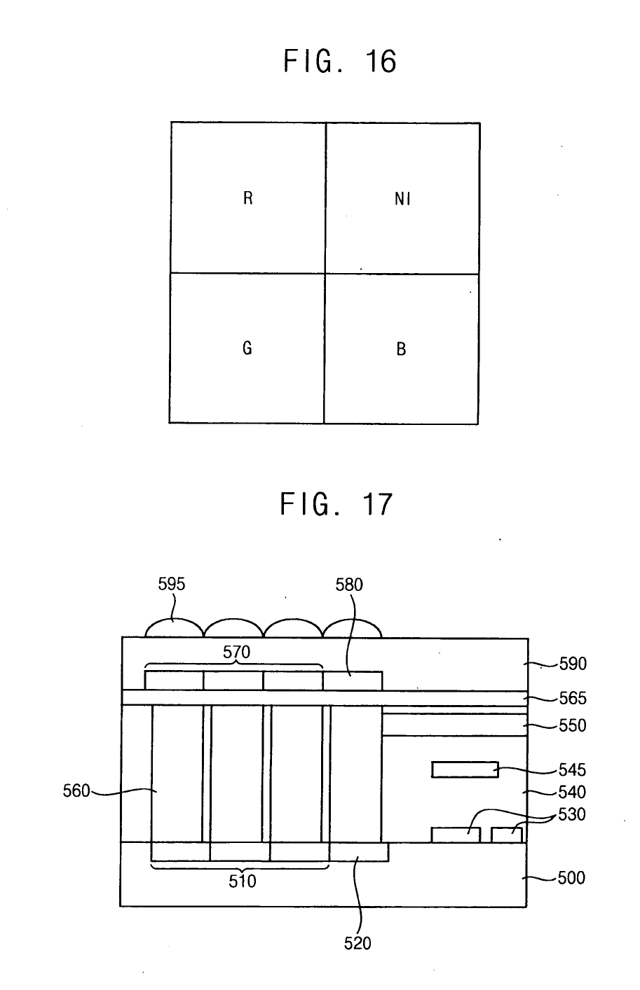

FIG. 16 is a plan view illustrating an RGB-Z chip according to example embodiments.

Referring to FIG. 16, an RGB-Z chip may include a CMOS image sensor (CIS) and a distance sensor. The CIS and the distance sensor may be built on a single substrate. The RGB-Z chip may have an RGB filter regions and a near infrared light filter region. The RGB filter regions may output image information. The near infrared light filter region may output distance information.

FIG. 17 is a cross-sectional view of a semiconductor device including the RGB-Z chip in FIG. 16, according to example embodiments.

Referring to FIG. 17, the semiconductor device may include a semiconductor substrate 500, RGB photodiode(s) 510, Z-diode(s) 520 and peripheral circuits 530. The RGB photodiode(s) 510 may be a portion of a color pixel array and may detect the image information. The Z-diode(s) 520 may be a portion of a distance pixel array and may detect the distance information.

The peripheral circuits 530 and an insulating interlayer 540 may be formed on the semiconductor substrate 500. A metal wiring 545 may be formed in/on the insulating interlayer 540. A light-inducing member 560 may be formed on the RGB photodiode(s) 510 and the Z-diode(s) 520. According to example embodiments, the light-inducing member 560 may include a resin layer.

A planarization layer 565 may be formed on the light-inducing member 560. An RGB filter 570 may be formed on the RGB photodiode 510. A near infrared light filter 580 may be formed on the Z-diode 520.

A protection layer 590 may be formed on the RGB filter 570 and the near infrared light filter 580. A lens 595 may be formed on the protection layer 590.

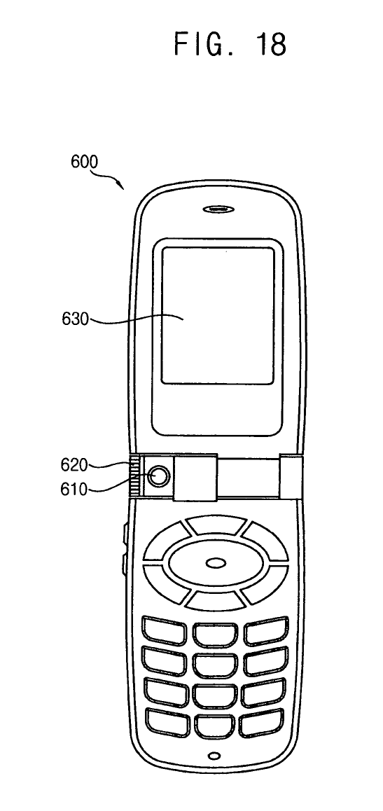

FIG. 18 is a front view of a cellular phone including the optical system of FIG. 3.

Referring to FIG. 18, the cellular phone 600 may include a camera lens module 610, a three-dimensional optical system 620 and a display 630. The three-dimensional optical system 620 may be somewhat similar to the optical system illustrated in FIG. 3, according to example embodiments. Thus, any further illustrations with respect to the three-dimensional optical system 620 are omitted herein for brevity. The display 630 may display image information and distance information output from the three-dimensional optical system 620. According to example embodiments, the cellular phone 600 may function as a navigator.

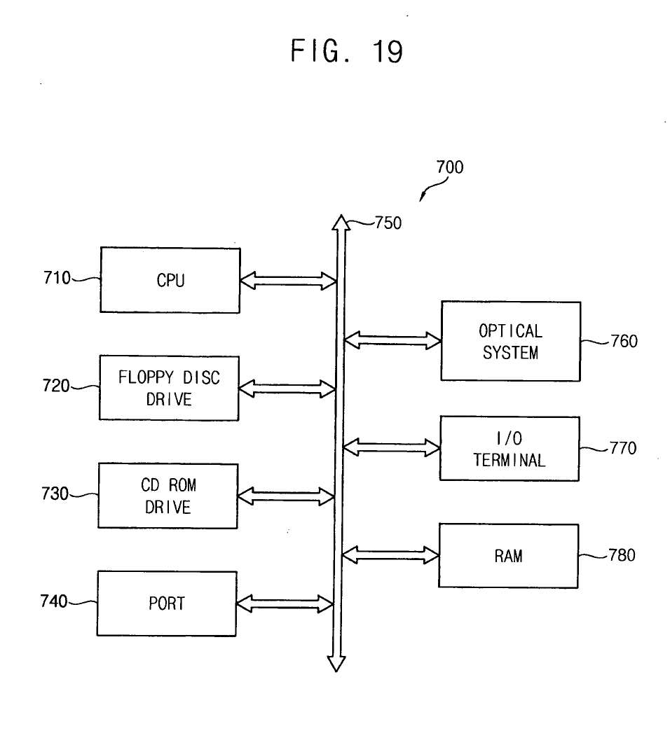

FIG. 19 is an example embodiment of a system including the optical system of FIG. 3.

Referring to FIG. 19, a system 700 may include a three-dimensional optical system 760 (somewhat similar to the three-dimensional optical system 620 of the example embodiment of FIG. 18). The system 700 may process signals including image information and distance information output from the three-dimensional optical system 760.

The system 700 may include input/output terminal(s) 770 and a central processing unit (CPU) 710. The CPU 710 may communicate with the input/output terminals 770 through a bus 750. Further, the CPU 710 may be connected with a floppy disc drive 720 and/or a CD-ROM drive 730, a port 740 and an RAM 780 through the bus 750 to output data from the three-dimensional optical system 760. Thus, when the system 700 may be built in a car, a driver may be provided with image and distance data in real time.

The port 740 may be connected to a video card, a sound card, a memory card, a USB element, or the like. Alternatively, the port 740 may communicate with other systems.

The three-dimensional optical system 760 may be integrated together with a CPU, a DSP, a microprocessor, a memory, or the like.

According to example embodiments, the system may provide the image information and the distance information. Thus, the system may be used in space-air industry, military industry, automobile industry, information and communication industry, or the like.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A three-dimensional image sensor comprising:
a color pixel array on a substrate;
a distance pixel array on the substrate;
a RGB filter on the color pixel array, the RGB filter configured to allow visible light having a first wavelength to pass through;
a near infrared light filter on the distance pixel array, the near infrared light filter configured to allow near infrared light having a second wavelength to pass through; and
a stack type filter on the RGB filter and the near infrared light filter, the stack type filter configured to allow light having a third wavelength between the first wavelength and the second wavelength to pass through.

2. The image sensor of claim 1, wherein the first wavelength is about 400 nm to about 700 nm.

3. The image sensor of claim 1, wherein the third wavelength is about 400 nm to about 900 nm.

4. The image sensor of claim 1, wherein the second wavelength is no less than about 830 nm.

5. The image sensor of claim 1, wherein the RGB filter blocks infrared light.

6. The image sensor of claim 1, wherein the near infrared light filter blocks visible light.

7. The image sensor of claim 1, wherein the RGB filter and the infrared filter include a polymer or a dye that selectively blocks a light of a desired wavelength.

8. The image sensor of claim 1, wherein the stack type filter includes layers of silicon oxide and titanium oxide of varying thicknesses.

9. The image sensor of claim 1, wherein the stack type filter is a single band filter.

10. The image sensor of claim 1, wherein the stack type filter is a dual band filter.

11. The image sensor of claim 1, wherein the near infrared filter has a multi-layered structure or a single layered structure including pigment mixtures or pigment and dye mixtures.

12. The image sensor of claim 1, wherein the near infrared light filter has a multi-layered structure including at least two inorganic materials that have different reflectivities.

13. An optical system including the image sensor of claim 1, and a camera lens module on the image sensor.

14. A system including the optical system of claim 13, wherein the optical system is configured to provide image information and distance information.

15. A semiconductor device, comprising:
a color pixel array on a substrate;
a distance pixel array on the substrate;
a light-inducing member on the color pixel array and the distance pixel array;
a RGB filter on the light-inducing member and configured to allow visible light to pass;
a near infrared light filter on the light-inducing member and configured to allow near infrared light to pass; and
a plurality of lenses on the RGB filter and the near infrared light filter.

16. The semiconductor device of claim 15, wherein the RGB filter and the near infrared light filter include a pigment or a dye.

17. The semiconductor device of claim 15, wherein the near infrared light filter has a multi-layered structure including at least two inorganic materials that have different reflectivities.

18. The semiconductor device of claim 15, wherein the lenses include microlenses.

19. The semiconductor device of claim 15, wherein the light-inducing member includes a resin layer.

20. An optical system comprising:
the semiconductor device of claim 15;
a stack type filter on the semiconductor device; and
a camera lens module on the stack type filter.
